(19) United States
(12) Patent Application Publication
(10) Pub. No.: US 2025/0254838 A1
(43) Pub. Date: Aug. 7, 2025

(54) HEAT DISSIPATION STRUCTURE

(71) Applicant: ASIA VITAL COMPONENTS (CHINA) CO., LTD., Shenzhen (CN)

(72) Inventors: Zhongyu Zhang, Shenzhen (CN); Zhiwei Li, Shenzhen (CN); Jingli Wang, Shenzhen (CN); Han-Min Liu, Shenzhen (CN)

(21) Appl. No.: 18/430,388

(22) Filed: Feb. 1, 2024

(51) Int. Cl. H05K 7/20

(52) U.S. Cl. CPC H05K 7/20418

(57) ABSTRACT

A heat dissipation structure includes a main body having a plurality of radiating fins. The radiating fins are coated on outer surfaces with a heat-exchange layer formed of a plurality of powder-like granules. With the heat-exchange layer, the main body may have increased surface areas for heat dissipation to provide upgraded heat dissipation efficiency.

### FIELD OF THE INVENTION

The present invention relates to a heat dissipation structure, and more particularly, to a heat dissipation structure that has increased surface areas for heat dissipation to provide upgraded heat dissipation efficiency.

### BACKGROUND OF THE INVENTION

Heat sink is the currently most popular heat dissipation element. The heat sink is in direct contact with a heat source in an electronic device, in order to provide more and larger surface areas of heat dissipation for efficient heat transfer and heat dissipation, lest heat produced by the heat source should be accumulated in the heat source to result in a broken or burnt-out electronic device.

Chips provided in the electronic apparatus or devices for data computing are the most seen heat sources. While the chips have more powerful computing ability, they produce more amount of heat than before. As a result, it is necessary to provide additional heat sinks sufficed for removing the high amount heat produced by the high-power heat sources, in order to provide a more effective solution for carrying away the produced heat.

Further, the currently developed electronic apparatus or devices are featured by compactness and accordingly, have very limited internal space. Since various electronic elements are densely and closely arranged in the current electronic apparatus and devices, there is not additional internal space allowing for any new or volume enlarged heat sink or other heat transfer element to increase the surface areas of heat dissipation (e.g. by providing increased number of radiating fins) and upgrade the heat dissipation efficiency of the heat sink.

It is therefore tried by the inventor to upgrade the heat dissipation performance of the heat sink by increasing additional heat dissipation areas of the heat sink without changing the original volume or dimensions of the heat sink.

### SUMMARY OF THE INVENTION

To effectively solve the problem in the prior art heat dissipation devices, a primary object of the present invention is to provide a heat dissipation structure, which is provided on outer surfaces with a heat-exchange layer, such that the heat dissipation structure may have upgraded heat dissipation efficiency without increasing its overall volume.

To achieve the above and other objects, the heat dissipation structure provided according to the present invention includes a main body.

The main body includes a plurality of radiating fins, and the radiating fins are coated on outer surfaces with a heat-exchange layer formed of a plurality of powder-like granules. In different embodiments, the main body may be a heat sink, a water block having an internal chamber, a water-powered bellow, or a condenser.

The powder-like granules forming the heat-exchange layer respectively have a plurality of contact surfaces, which advantageously increase the areas of heat dissipation on the outer surfaces of the radiating fins or the inner surfaces of the internal chamber of the heat dissipation structure. In the case of having only limited internal space for mounting the heat dissipation structure, the powder-like granules forming a plurality of the heat-exchange layers can provide numerous angular contact surfaces to enable further increased surface areas of heat dissipation on the radiating fins and upgraded overall heat dissipation efficiency of the heat dissipation structure without the need of changing the dimensions of the heat dissipation structure or the quantity of the radiating fins.

### BRIEF DESCRIPTION OF THE DRAWINGS

The structure and the technical means adopted by the present invention to achieve the above and other objects can be best understood by referring to the following detailed description of the preferred embodiment and the accompanying drawings, wherein

FIG. 1 is a perspective view of a heat dissipation structure according to a preferred embodiment of the present invention; and

FIG. 2 is an enlarged sectional view of the heat dissipation structure of FIG. 1.

### DETAILED DESCRIPTION OF THE PREFERRED EMBODIMENTS

The present invention will now be described with some preferred embodiments thereof.

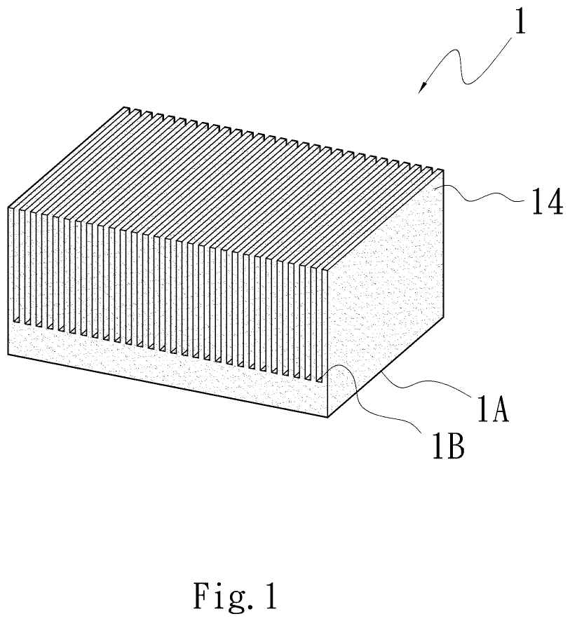

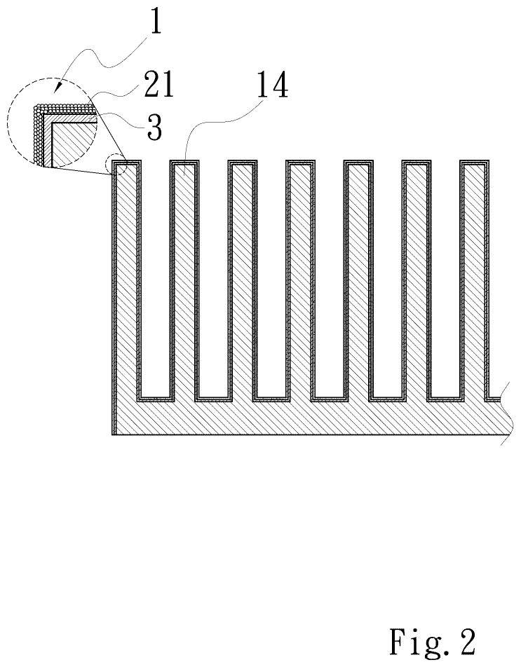

Please refer to FIGS. 1 and 2, in which a heat dissipation structure according to a preferred embodiment of the present invention is shown. As shown, the heat dissipation structure includes a main body 1, which is illustrated as a heat sink herein without being limited thereto. The main body 1 has a lower and an upper side, which are a heat absorption side 1A and a heat dissipation side 1B, respectively. The heat absorption side 1A is in direct contact with a heat source to absorb heat produced by the heat source. The heat dissipation side 1B has a plurality of radiating fins 11 that are extended from the heat dissipation side 1B and are spaced from one another. The radiating fins 11 have at least one heat-exchange layer 2 provide on their outer surfaces.

The heat-exchange layer 2 is formed of a plurality of powder-like granules 21 and can be coated on the outer surfaces of the radiating fins 11 by way of electroplating, spray finishing, sintering or printing.

When coating the powder-like granules 21 on the outer surfaces of the radiating fins 11 by way of spray finishing, a nickel layer 3 is first formed on the outer surfaces of the radiating fins 11 before applying the spray finishing, so that the powder-like granules 21 are coated on the nickel layer 3 with increased adherence to the radiating fins 11. Further, the powder-like granules 21 may be sparsely or densely distributed over the nickel-coated outer surfaces of the radiating fins 11. Alternatively, multiple layers of densely distributed powder-like granules 21 may be accumulated on the nickel-coated outer surfaces of the radiating fins 11. The nickel layer 3 may also serve as a protective layer on the radiating fins 11 when the radiating fins 11 and the powder-like granules 21 are made of different materials, so as to avoid the occurrence of eutectic corrosion between the two different materials, such as copper and aluminum.

The main body 1 may be made of an aluminum or a copper material, while the powder-like granules 21 in the heat-exchange layer 2 may be made of a material the same as or different from the material of the main body 1.

According to the present invention, the heat-exchange layer 2 provided on the outer surfaces of the radiating fins 11 is formed of a plurality of powder-like granules 21. These powder-like granules 21 provide a plurality of multi-angular contact surfaces, the total area of which is much larger than the contact surfaces provided by the original planar outer surfaces of the radiating fins 11 and accordingly, provide a plurality of multi-angular heat dissipation surfaces. With this arrangement, the powder-like granules 21 largely increase the heat dissipation areas of the radiating fins 11 without changing the overall volume of the heat sink and increasing the volume and dimensions of the radiating fins 11. When selecting a material with high heat transfer coefficient, such as copper, for forming the powder-like granules 21, the heat absorbed by the radiating fins 11 can be quickly transferred to the surfaces of the powder-like granules 21 and further be carried away from the radiating fins 11 by various cooling fluids, such as cooling airflow or cooling liquid (not shown), enabling upgraded heat dissipation efficiency of the heat sink and wide applications of the heat sink in water cooling or air cooling field.

Depending on different processing procedures, such as spray finishing, the heat-exchange layer 2 can be formed on the outer surfaces of the radiating fins 11 as one single layer with sparsely or densely distributed powder-like granules 21, or as a plurality of superposed layers of porous wick structure. Both distribution types of the powder-like granules 21 can upgrade the heat-exchange coefficient and heat dissipation performance of the radiating fins 11.

In another embodiment of the present invention, the main body 1 is a water block (not shown) having an internal chamber. In this case, the main body 1 is provided with an outlet and an inlet which are communicable with the chamber in the water block. In the chamber of the water block, there is provided a plurality of spaced radiating fins 11. The above-mentioned heat-exchange layer 2 formed of a plurality of powder-like granules 21 is coated on the outer surfaces of the radiating fins 11 and inner wall surfaces of the chamber of the water block.

When the present invention is used inside a heat dissipation structure for two-phase flow heat exchange, the powder-like granules 21 widely dispersed across inner wall surfaces of the heat dissipation structure form a rough surface texture, which can serve as a vaporization core to facilitate nucleate boiling in the heat dissipation structure. On the other hand, when a plurality of layers of densely distributed powder-like granules 21 are applied to the inner wall surfaces of the heat dissipation structure, they can form a porous layered structure (i.e. a porous structure is formed by the dispersed powder-like granules 21) to provide a working fluid with capillary forces and sufficient phase change space to enable enhanced two-phase flow heat exchange efficiency in an evaporator.

In the present invention, the heat-exchange layer 2 consisting of a plurality of powder-like granules 21 is formed directly on the outer surfaces of the radiating fins 11. For the existing problem in the heat sink field that the heat dissipation efficiency could not be further improved by additionally increasing the volumes or areas of the radiating fins 11 owing to the limited allowable dimensions of the heat sink, the present invention is no doubt an effective solution to the problem.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A heat dissipation structure, comprising:
a main body having a plurality of radiating fins; and the radiating fins being coated on outer surfaces with a heat-exchange layer formed of a plurality of powder-like granules.

2. The heat dissipation structure as claimed in claim 1, further comprising a nickel layer applied between the outer surfaces of the radiating fins and the heat-exchange layer.

3. The heat dissipation structure as claimed in claim 1, wherein the main body is made of an aluminum material and the powder-like granules are made of a copper material.

4. The heat dissipation structure as claimed in claim 1, wherein the powder-like granules forming the heat-exchange layer are sparsely distributed over the outer surfaces of the radiating fins.

5. The heat dissipation structure as claimed in claim 1, wherein the powder-like granules forming the heat-exchange layer are densely distributed over the outer surfaces of the radiating fins and form multiple superposed layers.

6. The heat dissipation structure as claimed in claim 1, wherein the main body has a heat absorption side and a heat dissipation side; and the radiating fins being extended from the heat dissipation side and being so arranged that they are spaced from one another.

7. The heat dissipation structure as claimed in claim 1, wherein the main body is a heat sink.
